(19) United States
(12) Patent Application Publication
(10) Pub. No.: US 2024/0387643 A1
(43) Pub. Date: Nov. 21, 2024

(54) MULTILAYER STRUCTURE, SEMICONDUCTOR DEVICE AND SEMICONDUCTOR APPARATUS

(71) Applicant: FLOSFIA INC., Kyoto (JP)

(72) Inventors: Mutsumi OKA, Kyoto (JP); Atsushi TERAI, Kyoto (JP); Hidetaka SHIBATA, Kyoto (JP)

(21) Appl. No.: 18/787,102

(22) Filed: Jul. 29, 2024

Related U.S. Application Data
(63) Continuation-in-part of application No. PCT/JP2023/002756, filed on Jan. 27, 2023.

(30) Foreign Application Priority Data
Jan. 31, 2022 (JP) 2022-013657

(51) Int. Cl. H01L 29/24; H01L 29/04; H01L 29/872

(52) U.S. Cl. CPC H01L 29/24; H01L 29/04; H01L 29/872

(57) ABSTRACT

Provided a multilayer structure including at least: a semiconductor layer containing a crystalline oxide semiconductor as a major component; and a conductive substrate layered on the semiconductor layer, wherein the multilayer structure has a first direction in a plane perpendicular to a layering direction of the multilayer structure and a second direction perpendicular or substantially perpendicular to the first direction, and a first coefficient of linear expansion being a coefficient of linear expansion in the first direction of the conductive substrate is smaller than a second coefficient of linear expansion being a coefficient of linear expansion in the second direction of the conductive substrate, and a third coefficient of linear expansion being a coefficient of linear expansion in the first direction of the semiconductor layer is smaller than a fourth coefficient of linear expansion being a coefficient of linear expansion in the second direction of the semiconductor layer.

### CROSS REFERENCE TO RELATED APPLICATION

This application is a continuation-in-part application of International Patent Application No. PCT/JP2023/002756 (Filed on Jan. 27, 2023), which claims the benefit of priority from Japanese Patent Application No. 2022-013657 (filed on Jan. 31, 2022).

The entire contents of the above applications, which the present application is based on, are incorporated herein by reference.

### FIELD OF THE INVENTION

The present disclosure relates to a multilayer structure, a semiconductor device, and a semiconductor apparatus that are useful as a power device and the like.

### DESCRIPTION OF THE RELATED ART

Semiconductor apparatus using gallium oxide (Ga₂O₃), which has a wide bandgap are attracting attention as next-generation switching elements that can achieve high breakdown voltage, low loss, and high heat resistance, and use in semiconductor apparatuses for power applications such as inverters is expected. Moreover, due to having a wide bandgap, semiconductor devices using gallium oxide are also expected to be applied to light-receiving devices and light-emitting devices, such as LEDs and sensors. The bandgap of gallium oxide may be controlled by using indium, aluminum, or a combination of the two, making an InAlGaO semiconductor have an extremely attractive family of material. Here, “InAlGaO semiconductor” indicates InₓAl_{y}Ga_{z}O₃ (0≤X≤2, 0≤Y≤2, 0≤Z≤2, X+Y+Z=1.5 to 2.5) and may be regarded as the material system that includes gallium oxide.

In a multilayer structure of a semiconductor film and a different substrate serving as a support substrate, there is a problem of degradation caused by warpage at high temperatures or cracking due to stress, especially when the multilayer structure is applied to power devices or when heated in the manufacturing process.

### SUMMARY OF THE INVENTION

According to an example of the present disclosure, there is provided a multilayer structure including at least: a semiconductor layer containing a crystalline oxide semiconductor as a major component; and a conductive substrate layered on the semiconductor layer, wherein the multilayer structure has a first direction in a plane perpendicular to a layering direction of the multilayer structure and a second direction perpendicular or substantially perpendicular to the first direction, and a first coefficient of linear expansion being a coefficient of linear expansion in the first direction of the conductive substrate is smaller than a second coefficient of linear expansion being a coefficient of linear expansion in the second direction of the conductive substrate, and a third coefficient of linear expansion being a coefficient of linear expansion in the first direction of the semiconductor layer is smaller than a fourth coefficient of linear expansion being a coefficient of linear expansion in the second direction of the semiconductor layer.

Thus, a multilayer structure, a semiconductor device and a semiconductor apparatus of the present disclosure have reduced degradation at a high temperature.

### BRIEF DESCRIPTION OF THE DRAWINGS

FIG. 1 is an example of a multilayer body used in an embodiment of the present disclosure.

FIG. 2 is an example of a bonded multilayer body used in the embodiment of the present disclosure.

FIG. 3 is an example of a semiconductor structure used in the embodiment of the present disclosure.

FIG. 4 is a schematic diagram of a suitable Schottky barrier diode (SBD) of the present disclosure.

FIG. 5 is a schematic diagram of a suitable Schottky barrier diode (SBD) of the present disclosure.

FIG. 6 is a schematic diagram of a suitable example of a metal oxide semiconductor field-effect transistor (MOSFET) of the present disclosure.

FIG. 7 is a schematic diagram illustrating part of a manufacturing process of the metal oxide semiconductor field-effect transistor (MOSFET) of FIG. 6.

FIG. 8 is a schematic diagram of a suitable example of a static induction transistor (SIT) of the present disclosure.

FIG. 9 is a schematic diagram of a suitable example of a Schottky barrier diode (SBD) of the present disclosure.

FIG. 10 is a schematic diagram of a suitable example of a metal oxide semiconductor field-effect transistor (MOSFET) of the present disclosure.

FIG. 11 is a schematic diagram of a suitable example of a junction field-effect transistor (JFET) of the present disclosure.

FIG. 12 is a configuration diagram of a mist CVD device used in an example of the present disclosure.

FIG. 13 is a schematic diagram of a suitable example of a semiconductor apparatus.

FIG. 14 is images of the surface of a semiconductor layer after heating in examples and comparative examples.

FIG. 15 is a block diagram illustrating an example of a control system applying the semiconductor device according to an embodiment of the disclosure.

FIG. 16 is a circuit diagram illustrating an example of the control system applying the semiconductor device according to an embodiment of the disclosure.

FIG. 17 is a block configuration diagram illustrating another example of the control system applying the semiconductor device according to an embodiment of the disclosure.

FIG. 18 is a circuit diagram illustrating another example of the control system applying the semiconductor device according to an embodiment of the disclosure.

FIG. 19 is a schematic diagram of a top surface of a conductive substrate according to the embodiment of the present disclosure.

FIG. 20 is a perspective view schematically illustrating the conductive substrate according to the embodiment of the present disclosure.

### DETAILED DESCRIPTION

The present inventors found that a multilayer structure including at least a semiconductor layer containing a crystalline oxide semiconductor as a major component, and a conductive substrate layered on the semiconductor layer, in which the multilayer structure has a first direction in a plane perpendicular to a layering direction of the multilayer structure and a second direction perpendicular or substantially perpendicular to the first direction, and a first coefficient of linear expansion being a coefficient of linear expansion in the first direction of the conductive substrate is smaller than a second coefficient of linear expansion being a coefficient of linear expansion in the second direction of the conductive substrate, and a third coefficient of linear expansion being a coefficient of linear expansion in the first direction of the semiconductor layer is smaller than a fourth coefficient of linear expansion being a coefficient of linear expansion in the second direction of the semiconductor layer can reduce degradation at high temperatures and solve the above-described problem in the related art. Additionally, the present inventors found that the multilayer structure is useful in a semiconductor device such as a power device, and a semiconductor apparatus.

Embodiments of the present disclosure will be described below with reference to the accompanying drawings. In the following description, the same parts and components are designated by the same reference numerals. The present embodiment includes, for example, the following disclosures.

### Structure 1

A multilayer structure including at least: a semiconductor layer containing a crystalline oxide semiconductor as a major component; and a conductive substrate layered on the semiconductor layer, wherein the multilayer structure has a first direction in a plane perpendicular to a layering direction of the multilayer structure and a second direction perpendicular or substantially perpendicular to the first direction, and a first coefficient of linear expansion being a coefficient of linear expansion in the first direction of the conductive substrate is smaller than a second coefficient of linear expansion being a coefficient of linear expansion in the second direction of the conductive substrate, and a third coefficient of linear expansion being a coefficient of linear expansion in the first direction of the semiconductor layer is smaller than a fourth coefficient of linear expansion being a coefficient of linear expansion in the second direction of the semiconductor layer.

### Structure 2

The multilayer structure according to [Structure 1], wherein a difference between the first coefficient of linear expansion and the second coefficient of linear expansion is 2.0 ppm/K or less.

### Structure 3

The multilayer structure according to [Structure 1] or [Structure 2], wherein the second coefficient of linear expansion is 10 ppm/K or less.

### Structure 4

The multilayer structure according to any one of [Structure 1] to [Structure 3], wherein the crystalline oxide semiconductor has at least a first crystallographic axis and a second crystallographic axis, a coefficient of linear expansion in the first crystallographic axis direction is smaller than a coefficient of linear expansion in the second crystallographic axis direction, and the crystalline oxide semiconductor is parallel or substantially parallel to a layering direction of the multilayer structure and the first crystallographic axis.

### Structure 5

The multilayer structure according to [Structure 4], wherein the crystalline oxide semiconductor has a corundum structure.

### Structure 6

The multilayer structure according to [Structure 5], wherein the first crystallographic axis is an m-axis.

### Structure 7

The multilayer structure according to [Structure 5] or [Structure 6], wherein the first direction of the semiconductor layer is an a-axis direction, and the second direction of the semiconductor layer is a c-axis direction.

### Structure 8

The multilayer structure according to any one of [Structure 1] to [Structure 7], wherein the crystalline oxide semiconductor contains at least one metal selected from aluminum, indium, and gallium.

### Structure 9

The multilayer structure according to any one of [Structure 1] to [Structure 8], wherein the crystalline oxide semiconductor contains at least gallium.

### Structure 10

The multilayer structure according to any one of [Structure 1] to [Structure 9], wherein a thickness of the conductive substrate is 200 μm or less.

### Structure 11

A semiconductor device including at least the multilayer structure described in any one of [Structure 1] to [Structure 10], and an electrode.

### Structure 12

A semiconductor apparatus including at least a semiconductor device bonded to a lead frame, a circuit board or a heat dissipating substrate by a bonding member, wherein the semiconductor device is the semiconductor device described in [Structure 11].

### Structure 13

A power conversion device using the semiconductor apparatus described in [Structure 12].

### Structure 14

A control system using the semiconductor apparatus described in [Structure 12].

A multilayer structure according to the present disclosure is a multilayer structure including at least a semiconductor layer containing a crystalline oxide semiconductor as a major component and a conductive substrate layered on the semiconductor layer, in which the multilayer structure has a first direction in a plane perpendicular to a layering direction of the multilayer structure and a second direction perpendicular or substantially perpendicular to the first direction, and a first coefficient of linear expansion being a coefficient of linear expansion in the first direction of the conductive substrate is smaller than a second coefficient of linear expansion being a coefficient of linear expansion in the second direction of the conductive substrate, and a third coefficient of linear expansion being a coefficient of linear expansion in the first direction of the semiconductor layer is smaller than a fourth coefficient of linear expansion being a coefficient of linear expansion in the second direction of the semiconductor layer.

In the embodiment of the present disclosure, for example, a manufacturing method is adopted which includes (1) layering the semiconductor layer on an underlying substrate directly or via another layer, (2) forming an electrode layer on the semiconductor layer as desired, and (3) layering the conductive substrate on the electrode layer via a conductive adhesive layer as desired, and removing the underlying substrate by using a known method. With this manufacturing method, the multilayer structure may be suitably manufactured. Hereinafter, embodiments of the present disclosure will be described in more detail with reference to the drawings as examples of the main processes (1) to (3) for manufacturing the multilayer structure.

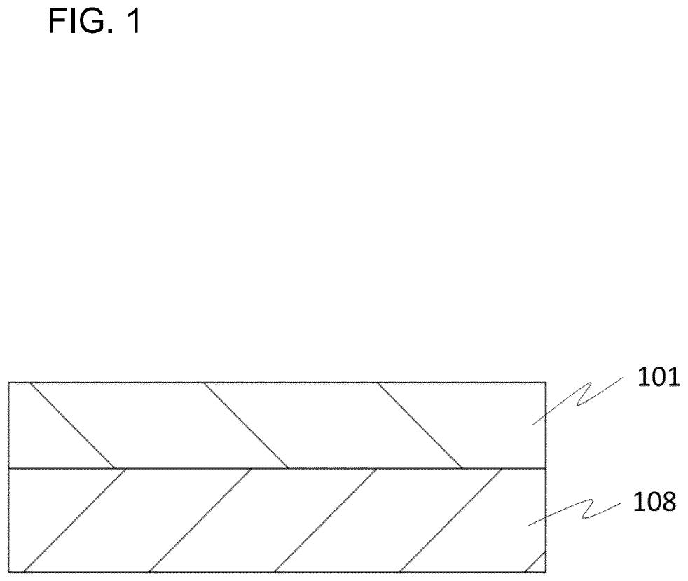

In process (1), the semiconductor layer is layered on the underlying substrate directly or via another layer. By process (1), for example, a multilayer body as illustrated in FIG. 1 may be obtained. In the multilayer body illustrated in FIG. 1, a semiconductor layer 101 is layered on an underlying substrate 108. In the present disclosure, the crystalline semiconductor film obtained by process (1) may be used as the semiconductor layer 101 (hereinafter also referred to as “semiconductor film”). Process (1) will be described below.

### (Underlying Substrate)

The underlying substrate is not particularly limited as long as it has a plate shape and serves as a support for the semiconductor film. The underlying substrate may be an insulator substrate, a semiconductor substrate, a metal substrate or a conductive substrate, but is preferably an insulator substrate or a substrate with a metal film on its surface. Examples of the underlying substrate include an underlying substrate containing a substrate material with a corundum structure as a major component, an underlying substrate containing a substrate material with a β-gallia structure as a major component, or an underlying substrate containing a substrate material with a hexagonal crystal structure as a major component. Herein, “major component” means that the substrate material with the aforementioned specific crystal structure contains, in atomic ratio, preferably 50% or more, more preferably 70% or more, and even more preferably 90% or more of the total components of the substrate material, and may be 100% of the substrate material.

The substrate material is not particularly limited and may be any known substrate material unless it interferes with the present disclosure. For example, α-Al₂O₃ (sapphire substrate) or α-Ga₂O₃ are suitable examples of substrate materials with the corundum structure described above, and a-plane sapphire substrates, m-plane sapphire substrates, r-plane sapphire substrates, c-plane sapphire substrates, or α-type gallium oxide substrates (a-plane, m-plane, or r-plane) and the like are more suitable examples. For example, β-Ga₂O₃ substrates, or mixed crystal substrates containing Ga₂O₃ and Al₂O₃ where Al₂O₃ is greater than 0 wt % and equal to or less than 60 wt %, are examples of the underlying substrate containing, as a major component, a substrate material with a β-gallia structure. Further, for example, SiC substrates, ZnO substrates, GaN substrates, and the like are examples of an underlying substrate containing, as a major component, a substrate material with a hexagonal crystal structure.

The semiconductor layer is not particularly limited as long as it contains a crystalline oxide semiconductor as a major component and that the coefficient of linear expansion in the first direction (hereinafter also referred to as “third coefficient of linear expansion”) is smaller than the coefficient of linear expansion in the second direction (hereinafter also referred to as “fourth coefficient of linear expansion”). Here, “coefficient of linear expansion” refers to a value measured according to JIS R 3102 (1995). The crystal structure of the crystalline oxide semiconductor is also not particularly limited unless it interferes with the present disclosure. Examples of the crystal structure of the crystalline oxide semiconductor include a corundum structure, a β-gallia structure, a hexagonal structure (e.g., an ε-type structure), an orthorhombic crystal structure (e.g., a κ-type structure), a cubic structure, or a tetragonal structure. In the embodiment of the present disclosure, the crystalline oxide semiconductor preferably has a corundum structure, a β-gallia structure or a hexagonal structure (e.g., an ε-type structure), and more preferably has a corundum structure. The crystalline oxide semiconductor is, for example, a metal oxide containing one or more metals selected from aluminum, gallium, indium, iron, chromium, vanadium, titanium, rhodium, nickel, cobalt and iridium. In the embodiment of the present disclosure, the crystalline oxide semiconductor preferably contains at least one metal selected from aluminum, indium and gallium, more preferably contains at least gallium, and most preferably is α-Ga₂O₃ or a mixed crystal thereof. Note that, the term “major component” means that the semiconductor layer contains the crystalline oxide semiconductor where an atomic ratio of gallium among all metal elements contained in the semiconductor layer is 0.5 or more. In the embodiment of the present disclosure, the atomic ratio of gallium among all the metal elements in the semiconductor layer is preferably 0.7 or more, more preferably 0.9 or more. In the embodiment of the present disclosure, the crystalline oxide semiconductor preferably has at least a first crystallographic axis and a second crystallographic axis perpendicular or substantially perpendicular to the first crystallographic axis, a coefficient of linear expansion in the first crystallographic axis direction is preferably smaller than a coefficient of linear expansion in the second crystallographic axis direction, and a layering direction of the multilayer structure and the first crystallographic axis arc preferably parallel or substantially parallel to each other. Herein, “substantially parallel” is not limited to a case where, for example, the layering direction of the multilayer structure and the first crystallographic axis direction are parallel and also includes a case where the angle between the layering direction and the first crystallographic axis direction is ±10° or less. Further, in a case where the crystalline oxide semiconductor has a corundum structure, the first crystallographic axis is preferably the m-axis or the a-axis, more preferably the m-axis. In this case, the first direction is preferably the a-axis direction, and the second direction is preferably the c-axis direction. Note that, for example, “the first direction is the a-axis direction” is not limited to a case where the first direction and the a-axis direction are parallel and also includes a case where the angle between the first direction and the a-axis direction is ±10° or less.

The thickness of the semiconductor layer is not particularly limited and may be less than 1 μm or more than 1 μm. In the embodiment of the present disclosure, the thickness is preferably 1 μm or more. The upper limit of the thickness of the semiconductor layer is not particularly limited unless it interferes with the present disclosure, but is preferably 30 μm or less. The surface area of the semiconductor layer is not particularly limited and may be 1 mm² or more or 1 mm² or less, but is preferably 10 mm² to 300 cm², more preferably 10 mm² to 100 cm². The semiconductor layer is typically monocrystalline but may be polycrystalline. Further, the semiconductor layer is preferably a multilayer film including at least a first semiconductor layer and a second semiconductor layer and, in a case where a Schottky electrode is provided on the first semiconductor layer, is also preferably a multilayer film in which the carrier density of the first semiconductor layer is smaller than the carrier density of the second semiconductor layer. Note that, in this case, the second semiconductor layer typically contains a dopant, and the carrier density of the semiconductor layer may be set as appropriate by adjusting the doping amount.

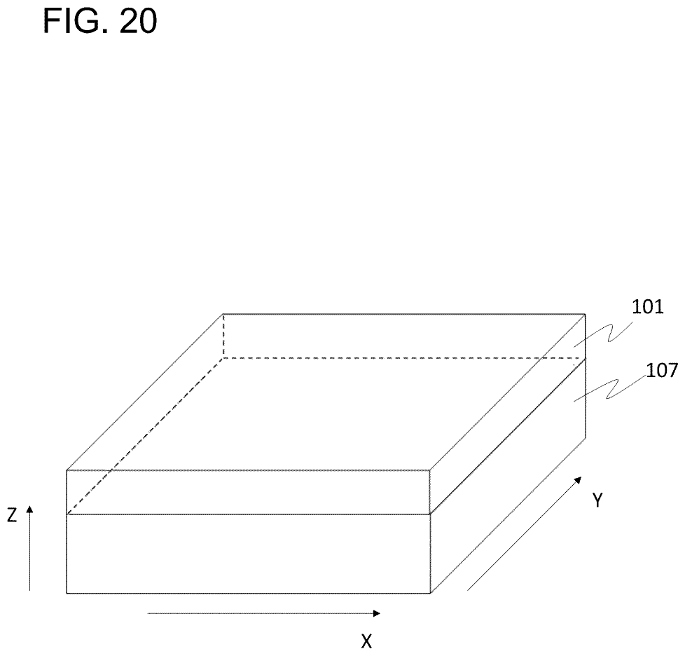

FIG. 20 is a perspective view schematically illustrating the multilayer structure including at least the conductive substrate and the semiconductor layer. In FIG. 20, although the conductive adhesive layer, the electrode layer and other components are not illustrated, a configuration in which the multilayer structure in FIG. 20 further includes the conductive adhesive layer and the electrode layer is also included in the embodiment of the present disclosure. The Z-direction in FIG. 20 represents the layering direction of the multilayer structure. The X-direction and the Y-direction in FIG. 20 represent the first direction and the second direction, respectively. Further, the first crystallographic axis direction (e.g., the m-axis direction or a-axis direction) of the crystalline oxide semiconductor described above is parallel or substantially parallel to the Z-direction (layering direction) in FIG. 20, and the second crystallographic axis direction (e.g., the c-axis direction) of the crystalline oxide semiconductor is parallel or substantially parallel to the Y-axis direction in FIG. 20.

The semiconductor layer preferably contains a dopant. The dopant is not particularly limited and may be any known dopant. Examples of the dopant include n-type dopants such as tin, germanium, silicon, titanium, zirconium, vanadium or niobium, and p-type dopants such as magnesium, calcium and zinc. In the embodiment of the present disclosure, the n-type dopants are preferably Sn, Ge or Si. The content of the dopant is preferably 0.00001 atom % or more, more preferably 0.00001 atom % to 20 atom %, most preferably 0.00001 atom % to 10 atom % in the composition of the semiconductor layer. More specifically, the concentration of the dopant may typically be about 1×10¹⁶/cm³ to 1×10²²/cm³, or the concentration of the dopant may be as low as, for example, 1×10¹⁷/cm³ or less. Further, according to the present disclosure, the dopant may be contained at a high concentration of about 1×10¹⁹/cm³ or more. In the embodiment of the present disclosure, the dopant is preferably contained at a carrier concentration of 1×10¹⁷/cm³ or more.

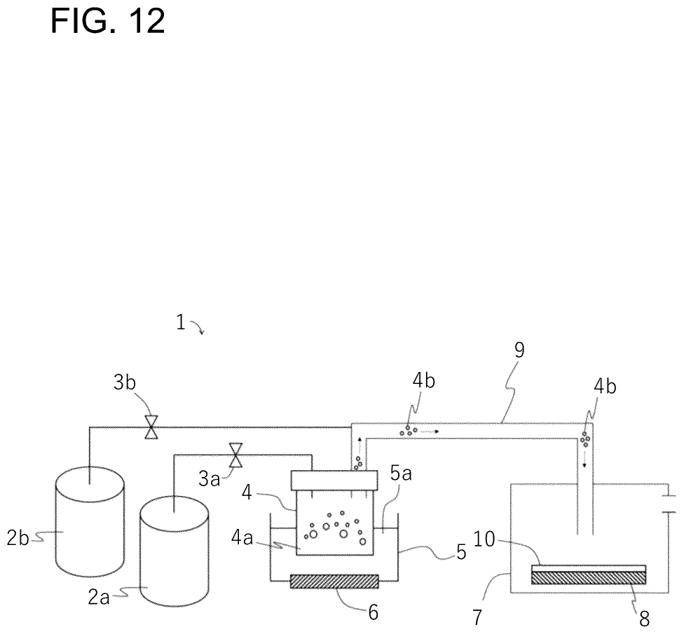

The semiconductor layer may be formed using known method. For example, CVD, MOCVD, MOVPE, mist CVD, mist epitaxy, MBE, HVPE, pulse growth or ALD are examples of methods of forming the semiconductor layer. In the embodiment of the present disclosure, the method of forming the semiconductor layer is preferably mist CVD or mist epitaxy. In mist CVD or mist epitaxy, for example, the mist CVD apparatus illustrated in FIG. 12 is used to atomize a raw material solution (atomization process), suspend droplets, after the atomization, transport the resulting atomized droplets onto the substrate by using a carrier gas (transport process), and then thermally react the atomized droplets in a deposition chamber. Then, the semiconductor layer is formed by layering a semiconductor film containing a crystalline oxide semiconductor as a major component on the substrate by thermally reacting the atomized droplets in a deposition chamber (deposition process).

### (Atomization Process)

In the atomization process, the raw material solution is atomized. The method of atomizing the raw material solution is not particularly limited as long as it can atomize the raw material solution and may be any known method. In the embodiment of the present disclosure, an atomization method using ultrasonic waves is preferred. Atomized droplets obtained by using ultrasonic waves are desirable because they have zero initial velocity and are suspended in air. For example, atomized droplets obtained by using ultrasonic waves are very suitable because they are a mist that may be transported as a gas suspended in space rather than sprayed, so no damage is caused by collision energy. The droplet size is not limited and may be several millimeters, preferably 50 μm or less, and more preferably 100 nm to 10 μm.

### (Raw Material Solution)

The raw material solution is not particularly limited as long as it is atomizable or dropletizable and contains a raw material capable of forming a semiconductor film, and may be an inorganic material or an organic material. In the embodiment of the present disclosure, the raw material is preferably a metal or metal compound, and more preferably contains one or more metals selected from aluminum, gallium, indium, iron, chromium, vanadium, titanium, rhodium, nickel, cobalt and iridium.

In the embodiment of the present disclosure, a metal dissolved or dispersed in an organic solvent or water in the form of a complex or a salt may be suitably used as the raw material solution. Examples of the complex include acetylacetonate complexes, carbonyl complexes, ammine complexes, and hydride complexes. Examples of the salt include organometallic salts (e.g., metal acetates, metal oxalates, and metal citrates), metal sulfides, metal nitrides, metal phosphates, and metal halides (e.g., metal chlorides, metal bromides, and metal iodides).

Further, an additive such as hydrohalogenated acid and an oxidizing agent is preferably mixed into the raw material solution. Examples of the hydrohalogenic acid include hydrobromic acid, hydrochloric acid, and hydroiodic acid, among which hydrobromic acid or hydroiodic acid is preferred because it is capable of more efficiently suppressing the generation of abnormal grains. Examples of the oxidant include hydrogen peroxide (H₂O₂), sodium peroxide (Na₂O₂), barium peroxide (BaO₂), benzoyl peroxide (C₆H₅CO)₂O₂ and other peroxides, hypochlorous acid (HClO), perchloric acid, nitric acid, ozone water, and organic peroxides such as peracetic acid and nitrobenzene.

The raw material solution may contain a dopant. By including a dopant in the raw material solution, doping may be performed satisfactorily. The dopant is not particularly limited unless it interferes with the present disclosure. Examples of the dopant include n-type dopants such as tin, germanium, silicon, titanium, zirconium, vanadium and niobium, and p-type dopants such as Mg, H, Li, Na, K, Rb, Cs, Fr, Be, Ca, Sr, Ba, Ra, Mn, Fe, Co, Ni, Pd, Cu, Ag, Au, Zn, Cd, Hg, Ti, Pb, N, and P. The content of the dopant is set as appropriate by using a calibration curve that indicates the relationship of the concentration of the dopant in the raw material to the desired carrier density.

The solvent of the raw material solution is not particularly limited and may be an inorganic solvent such as water, an organic solvent such as alcohol, or a mixture of an inorganic solvent and an organic solvent. In the embodiment of the present disclosure, the solvent preferably contains water.

### (Transport Process)

In the transport process, the atomized droplets are transported into the deposition chamber by a carrier gas. The carrier gas is not particularly limited unless it interferes with the present disclosure. For example, inert gases such as oxygen, ozone, nitrogen and argon, or reducing gases such as hydrogen gas and forming gas are suitable examples. One type of carrier gas may be used, or two or more types may be used, and a dilution gas with a reduced flow rate (e.g., 10 times dilution gas) may be further used as a second carrier gas. The carrier gas may be supplied not only at one supply point but also at two or more supply points. The flow rate of the carrier gas is not particularly limited, but is preferably 0.01 to 20 L/min, more preferably 1 to 10 L/min. In the case of dilution gas, the flow rate of the dilution gas is preferably 0.001 to 5 L/min, more preferably 0.1 to 3 L/min.

### (Deposition Process)

In the deposition process, the semiconductor film is deposited on the substrate by thermally reacting the atomized droplets in the deposition chamber. The thermal reaction is sufficient as long as the atomized droplets are reacted with heat, and the reaction conditions are not particularly limited unless it interferes with the present disclosure. In this process, the thermal reaction is typically carried out at a temperature greater than or equal to the evaporation temperature of the solvent, but preferably at a temperature not too high (e.g., 1000° C.) or less, more preferably 650° C. or less, and most preferably 300° C. to 650° C. The thermal reaction may be carried out under any of vacuum, a non-oxygen atmosphere (e.g., inert gas atmosphere), a reducing gas atmosphere, and an oxygen atmosphere, unless it interferes with the present disclosure, but is preferably carried out under an inert gas atmosphere or an oxygen atmosphere. The thermal reaction may also be performed under atmospheric pressure, under pressurized conditions, or under depressurized conditions. In the embodiment of the present disclosure, the thermal reaction is preferably performed under atmospheric pressure. The film thickness may be set by adjusting the deposition time.

In the embodiment of the present disclosure, annealing treatment may be performed after the above-described deposition process. The temperature of the annealing treatment is not particularly limited unless it interferes with the present disclosure, and is typically from 300° C. to 650° C., preferably from 350° C. to 550° C. The time for the annealing treatment is typically from 1 minute to 48 hours, preferably from 10 minutes to 24 hours, and more preferably from 30 minutes to 12 hours. Note that the annealing treatment may be performed under any atmosphere unless it interferes with the present disclosure. The annealing treatment may be performed under a non-oxygen atmosphere or an oxygen atmosphere. The non-oxygen atmosphere includes, for example, an inert gas atmosphere (e.g., nitrogen atmosphere) or a reducing gas atmosphere. In the embodiment of the present disclosure, an inert gas atmosphere is preferred, and a nitrogen atmosphere is more preferred.

In the embodiment of the present disclosure, the semiconductor film may be directly deposited on the underlying substrate, or the semiconductor film may be deposited via another layer, such as a stress relaxation layer (e.g., buffer layer or ELO layer) or an exfoliation sacrifice layer. The method of forming each layer is not limited and may be any known method, but mist CVD is preferred in the embodiment of the present disclosure.

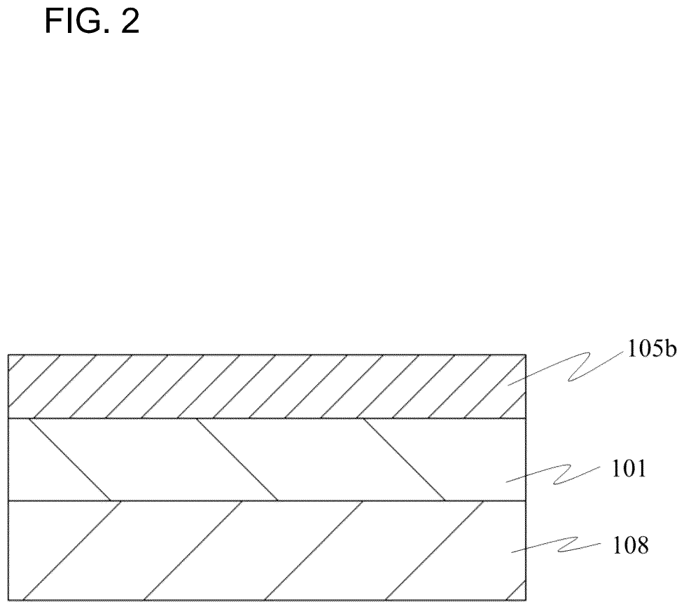

In process (2), an electrode layer 105b is formed on the semiconductor layer 101 as desired. By performing process (2), a multilayer body such as that illustrated in FIG. 2 may be obtained. The multilayer body in FIG. 2 is composed of an underlying substrate 108, the semiconductor layer 101, and the electrode layer 105b.

The electrode layer is not particularly limited as long as it is conductive and does not interfere with the purpose of the disclosure. The constituent material of the electrode layer may be a conductive inorganic material or a conductive organic material. In the embodiment of the present disclosure, the material of the electrode layer is preferably a metal. The metal may suitably be, for example, at least one metal selected from Group 4 to Group 10 of the periodic table. Group 4 metals include titanium (Ti), zirconium (Zr), and hafnium (Hf). Group 5 metals include vanadium (V), niobium (Nb), and tantalum (Ta). Group 6 metals include chromium (Cr), molybdenum (Mo), and tungsten (W). Group 7 metals include manganese (Mn), technetium (Tc), and rhenium (Re). Group 8 metals include iron (Fe), ruthenium (Ru), and osmium (Os). Group 9 metals include cobalt (Co), rhodium (Rh), and iridium (Ir). Group 10 metals include nickel (Ni), palladium (Pd), and platinum (Pt). In the embodiment of the present disclosure, the electrode layer preferably contains at least one metal selected from Group 4 or Group 9 of the periodic table, and more preferably contains a Group 9 metal. The thickness of the electrode layer is not particularly limited, but is preferably 0.1 nm to 10 um, more preferably 5 nm to 500 nm, and most preferably 10 nm to 200 nm. In the embodiment of the present disclosure, the electrode layer may comprise two or more layers having different compositions from each other.

The method of forming the electrode layer is not particularly limited and may be any known method. Specific examples of the method of forming the electrode layer or other electrode layers include dry methods and wet methods. Dry methods include sputtering, vacuum deposition, and CVD. Wet methods include screen printing and die coating.

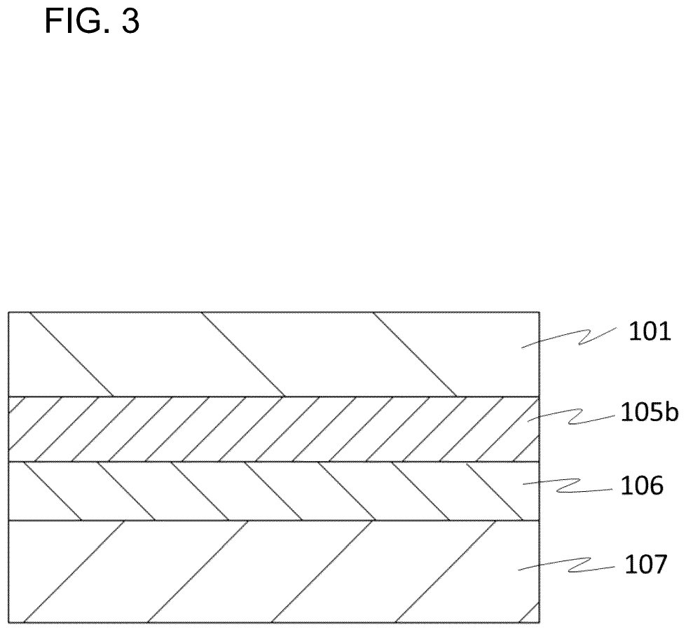

In process (3), the conductive substrate is layered on the electrode layer via a conductive adhesive layer, as desired, and the underlying substrate is removed using a known method. By process (3), for example, the multilayer body illustrated in FIG. 3 may be obtained. In the multilayer body illustrated in FIG. 3, the electrode layer 105b is bonded via a conductive adhesive layer 106 on a conductive substrate 107, and the semiconductor layer 101 is layered on the electrode layer 105b. The method of removing the underlying substrate may be, for example, applying mechanical impact, applying heat and using thermal stress, applying vibration such as ultrasonic waves, etching, grinding, ion implantation such as the Smart-Cut method followed by heat treatment, laser lift-off, and a combination of these methods.

The conductive adhesive layer is not particularly limited as long as it is capable of bonding the electrode layer and the conductive substrate. Examples of the constituent material of the conductive adhesive layer include metals including at least one selected from Al, Au, Pt, Ag, Ti, Ni, Bi, Cu, Ga, In, Pb, Sn and Zn and their metal oxides, and eutectic materials (e.g., Au—Sn). In the embodiment of the present disclosure, the conductive adhesive layer preferably has a porous structure. In a case where the conductive adhesive layer has a porous structure, the conductive adhesive layer preferably contains metal particles, more preferably contains metal particles containing at least one metal selected from Au, Pt, Ag, Ti, Ni, Bi, Cu, Ga, In, Pb, Sn and Zn, and most preferably includes metal particles containing a precious metal. Examples of the precious metal include at least one metal selected from Au, Ag, Pt, Pd, Rh, Ir, Ru, and Os. In the embodiment of the present disclosure, the precious metal is preferably Ag. Further, in the embodiment of the present disclosure, the conductive adhesive layer preferably contains sintered metal particles, and more preferably contains sintered silver particles. By using such a preferred conductive adhesive layer, better adhesion to the electrode layer and the conductive substrate may be achieved without compromising the electrical characteristics of the semiconductor device. In addition, the conductive adhesive layer may be a single layer or has multiple layers. The thickness of the conductive adhesive layer is not particularly limited unless it interferes with the present disclosure, but is preferably from 10 nm to 200 μm, and more preferably from 10 nm to 50 μm. In addition, the conductive adhesive layer is typically amorphous, but may contain sub-components such as crystals. The method of forming the conductive adhesive layer is not particularly limited and any known application method may be used.

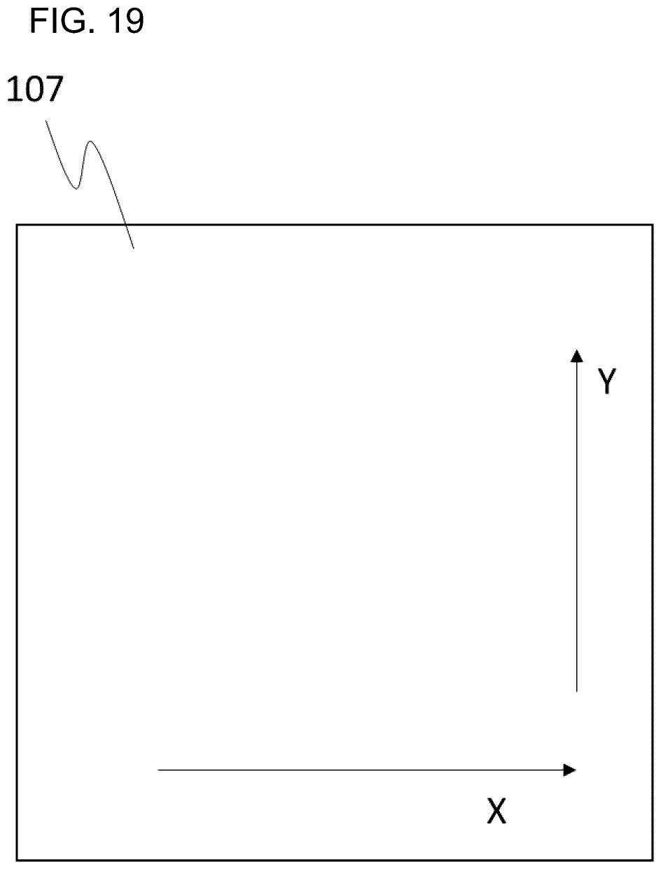

The conductive substrate is not particularly limited as long as the conductive substrate is conductive, is able to support the semiconductor layer, and a coefficient of linear expansion in the first direction (hereinafter also referred to as “first coefficient of linear expansion”) is smaller than a coefficient of linear expansion in the second direction (hereinafter also referred to as “second coefficient of linear expansion”). In the embodiment of the present disclosure, the conductive substrate preferably includes at least a first metal and a second metal different to the first metal. FIG. 19 schematically illustrates a top surface of the conductive substrate. The conductive substrate 107 in FIG. 19 has a first direction (X direction in FIG. 19) and a second direction (Y direction in FIG. 19) perpendicular or substantially perpendicular to the first direction in a plane. Here, the term “substantially perpendicular” includes a case where the angle between the first direction and the second direction is 90°±10°. Here, the term “coefficient of linear expansion” refers to a value measured according to JIS R 3102 (1995). The difference between the first coefficient of linear expansion and the second coefficient of linear expansion is not particularly limited unless it interferes with the present disclosure. In the embodiment of the present disclosure, the difference between the first coefficient of linear expansion and the second coefficient of linear expansion is preferably 3.0 ppm/K or less, more preferably 2.0 ppm/K or less. Note that the upper limit of the second coefficient of linear expansion is also not particularly limited unless it interferes with the present disclosure. The upper limit of the second coefficient of linear expansion is typically 12 ppm/K or less, and preferably 10 ppm/K or less. Such a preferred configuration allows for better reduction of degradation of the semiconductor layer at high temperatures, even when there is a difference in the coefficients of linear expansion between the conductive substrate and the semiconductor layer. Note that, in the multilayer structure illustrated in FIG. 20, the first coefficient of linear expansion of the conductive substrate 107 is a coefficient of linear expansion in the X-direction in FIG. 20, and the second coefficient of linear expansion of the conductive substrate 107 is a coefficient of linear expansion in the Y-direction in FIG. 20.

The first metal and/or the second metal are not particularly limited unless it interferes with the present disclosure. The embodiment of the present disclosure preferably includes a first metal and a second metal having a greater Young's modulus than the first metal, in which the mass ratio of the second metal in the conductive substrate is greater than the mass ratio of the first metal. Such a preferred configuration can, for example, better reduce degradation (cracking, etc.) of the semiconductor layer at high temperatures, even when there is a difference in the linear expansion coefficients between the semiconductor layer and the conductive substrate. Examples of the combination of the first metal and the second metal in the conductive substrate include copper (Cu)-tungsten (W), copper (Cu)-molybdenum (Mo), lanthanum (La)-molybdenum (Mo), yttrium (Y)-molybdenum (Mo), rhenium (Re)-molybdenum (Mo), molybdenum (Mo)-tungsten (W), niobium (Nb)-molybdenum (Mo), and tantalum (Ta)-molybdenum (Mo). In the embodiment of the present disclosure, the first metal and/or the second metal is at least one metal selected from Group 6 metals of the periodic table and Group 11 metals of the periodic table. Examples of Group 6 metals include chromium (Cr), molybdenum (Mo), and tungsten (W). Examples of Group 11 metals include copper (Cu), silver (Ag), and gold (Au). In the embodiment of the present disclosure, the first metal is preferably a Group 11 metal (e.g., copper) and the second metal is preferably a Group 6 metal (e.g., molybdenum). With such a preferred combination of the first metal and the second metal, degradation at high temperatures may be better controlled while maintaining the heat dissipation properties of the multilayer structure or the semiconductor device. In the embodiment of the present disclosure, in a case where the conductive substrate contains molybdenum and copper, a Cu—Mo composite substrate obtained by the impregnation method in which copper is impregnated into molybdenum pressed powder (hereinafter also simply referred to as “Cu—Mo composite substrate”) is preferably used as the conductive substrate. In the present disclosure, it is also preferred that the first direction of the conductive substrate is the rolling direction.

The Young's modulus of the first metal is not particularly limited unless it interferes with the present disclosure. The Young's modulus of the first metal is typically 200 GPa or less and is suitably, for example, 150 GPa or less. The lower limit of the Young's modulus of the first metal is not particularly limited. In the embodiment of the present disclosure, the Young's modulus of the first metal is preferably 100 GPa or more. Further, the Young's modulus of the second metal is not particularly limited unless it interferes with the present disclosure. The Young's modulus of the second metal is suitably, for example, 300 GPa or more. The Young's modulus of the conductive substrate is suitably, for example, 200 GPa or more. Such a preferred configuration may better reduce the degradation of the semiconductor layer at high temperatures, even when, for example, the coefficient of linear expansion of the semiconductor layer and the coefficient of linear expansion of the conductive substrate are different. The mass ratio of the first metal and the second metal in the conductive substrate is not particularly limited unless it interferes with the present disclosure. In the embodiment of the present disclosure, the mass ratio of the second metal is preferably 60 mass % or more. The upper limit of the mass ratio of the second metal is also not particularly limited. In the embodiment of the present disclosure, the upper limit is preferably 85 mass % or less, more preferably 70 mass % or less. Note that a mass ratio of the first metal in the conductive substrate is typically 40 mass % or less, preferably 30 mass % or less. The lower limit of the mass ratio of the first metal is not particularly limited. In the embodiment of the present disclosure, the mass ratio of the first metal is 10 mass % or more and 15 mass % or more. By setting such a preferred ratio, degradation at high temperatures may be better reduced while maintaining heat dissipation. In the embodiment of the present disclosure, the conductive substrate may include a metal film on its surface. Examples of the constituent metal of the metal layer include one or more metals selected from gallium, iron, indium, aluminum, copper, vanadium, titanium, chromium, rhodium, nickel, cobalt, zinc, magnesium, calcium, silicon, yttrium, strontium, and barium. Further, the thickness of the conductive substrate is not particularly limited, but is preferably 200 μm or less as this can provide better heat dissipation without impairing the electrical characteristics of the semiconductor device. The area of the conductive substrate is also not particularly limited. In the embodiment of the present disclosure, the area of the conductive substrate is preferably substantially identical to the area of the semiconductor layer. Note that the term “substantially identical” includes, for example, a case where the area of the conductive substrate is the same as the area of the semiconductor layer, and a case where the ratio of the area of the conductive substrate to the area of the semiconductor layer is within a range of 0.9 to 1.4.

Further, in the embodiment of the present disclosure, the conductive substrate is preferably made of a top layer and a bottom layer, each of which includes a layer containing copper. By giving the conductive substrate such a preferred configuration, heat dissipation and mounting ability in a case where the multilayer structure is used in a semiconductor device may be further improved. Additionally, in a case where the top layer and/or the bottom layer of the conductive substrate contains a Group 11 metal, bonding between the electrode layer and the conductive substrate can also be achieved without using the conductive adhesive layer, and warpage and thermal resistance of the semiconductor device may be improved more effectively. In this case, for example, the electrode layer and the conductive substrate may be industrially advantageously bonded without using the conductive adhesive layer by diffusion bonding the copper-containing layer located at the top surface of the electrode layer on the conductive substrate side and the copper-containing layer located at the top surface of the multilayer structure of the conductive substrate on the electrode layer side.

In the embodiment of the present disclosure, after process (3), the crystals of the crystalline semiconductor film may be re-grown, or a different semiconductor layer, another electrode layer, or the like may be formed on the semiconductor layer.

In the embodiment of the present disclosure, in a case where the multilayer structure is used in a semiconductor device, another electrode layer is preferably further provided on a surface opposite to the surface on which the electrode layer is layered on the semiconductor layer. With this configuration, by using a multilayer structure in which the conductive substrate, the conductive adhesive layer, the electrode layer, the semiconductor layer, and the other electrode layer are layered in this order, the forward characteristics of the semiconductor device as a vertical device in which current flows in the thickness direction of the semiconductor layer may be improved. The other electrode layer is not particularly limited as long as the electrode layer is conductive and does not interfere with the present disclosure. The constituent material of the other electrode layer may be a conductive inorganic material or a conductive organic material. In the embodiment of the present disclosure, the material of the other electrode layer is preferably a metal. Suitable examples of the metal include at least one metal selected from Group 8 to Group 13 metals of the periodic table. Examples of Groups 8 to 10 metals include the metals exemplified as Group 8 to 10 metals in the description of the electrode layer above. Examples of Group 11 metals include copper (Cu), silver (Ag), and gold (Au). Examples of Group 12 metals include zinc (Zn) and cadmium (Cd). Examples of Group 13 metals include aluminum (Al), gallium (Ga), and indium (In). In the embodiment of the present disclosure, the other electrode layer preferably contains at least one metal selected from Group 11 and Group 13 metals, and more preferably contains at least one metal selected from silver, copper, gold, and aluminum. The thickness of the other electrode layer is not particularly limited but is preferably 1 nm to 500 μm, more preferably 10 nm to 100 μm, and most preferably 0.5 μm to 10 μm.

The method of forming the other electrode layer is not particularly limited and may be any known method. Specific examples of the method of forming the electrode layer or the other electrode layer include dry and wet methods. Examples of dry methods include sputtering, vacuum deposition, and CVD. Examples of wet methods include screen printing and die coating.

The multilayer structure of the present disclosure are useful for various semiconductor devices and are especially useful for power devices. In addition, semiconductor devices may be classified into horizontal devices (horizontal element), in which electrodes are formed on one side of the semiconductor layer and current flows in a direction perpendicular to the thickness direction of the semiconductor layer, and vertical devices (vertical element), in which electrodes are provided on the front and back sides of the semiconductor layer respectively and current flows in a thickness direction of the semiconductor layer. In the embodiment of the present disclosure, the semiconductor device may be suitably used for both horizontal devices and vertical devices but is especially preferable used in vertical devices. Examples of the semiconductor device include Schottky barrier diodes (SBDs), metal semiconductor field effect transistors (MESFETs), high electron mobility transistors (HEMTs), metal oxide semiconductor field effect transistors (MOSFETs), static induction transistors (SITs), junction field effect transistors (JFETs), insulated gate bipolar transistors (IGBTs), and light-emitting diodes. In the embodiment of the present disclosure, the semiconductor device is preferably an SBD, MOSFET, SIT, JFET or IGBT, more preferably an SBD, MOSFET or SIT, and most preferably an SBD.

Hereinafter, suitable examples of the multilayer structure when used in a semiconductor device will be described with reference to the drawings, but the present disclosure is not limited to these examples. In the semiconductor device described below, other layers (e.g., insulator layer, semi-insulator layer, conductor layer, semiconductor layer, buffer layer or other intermediate layer, etc.) may be further included, and the buffer layer may be omitted as appropriate, unless it interferes with the present disclosure.

### (SBD)

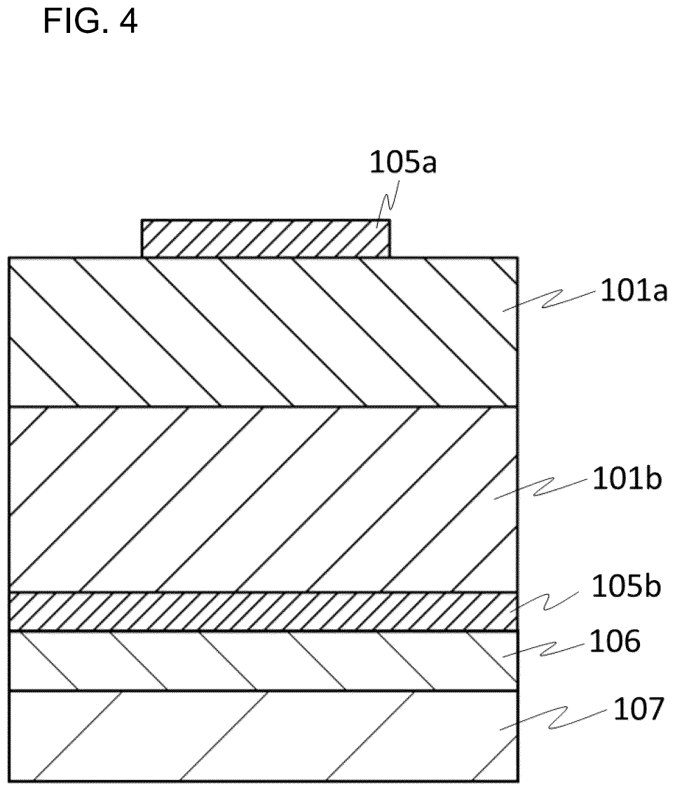

FIG. 4 illustrates an example of a Schottky barrier diode (SBD). The SBD of FIG. 4 includes an n-semiconductor layer 101a, an n+ semiconductor layer 101b, the conductive adhesive layer 106, the conductive substrate 107, a Schottky electrode 105a, and an ohmic electrode 105b.

The material of the Schottky electrode and the ohmic electrode may be a known electrode material. Examples of the electrode material include a metal such as Al, Mo, Co, Zr, Sn, Nb, Fe, Cr, Ta, Ti, Au, Pt, V, Mn, Ni, Cu, Hf, W, Ir, Zn, In, Pd, Nd or Ag or their alloys, a metal oxide conductive film such as tin oxide, zinc oxide, indium oxide, indium tin oxide (ITO), and indium zinc oxide (IZO), organic conductive compounds such as polyaniline, polythiophene and polypyrrole, or mixtures thereof. The Schottky electrode and the ohmic electrode may be formed by a known method such as vacuum evaporation or sputtering.

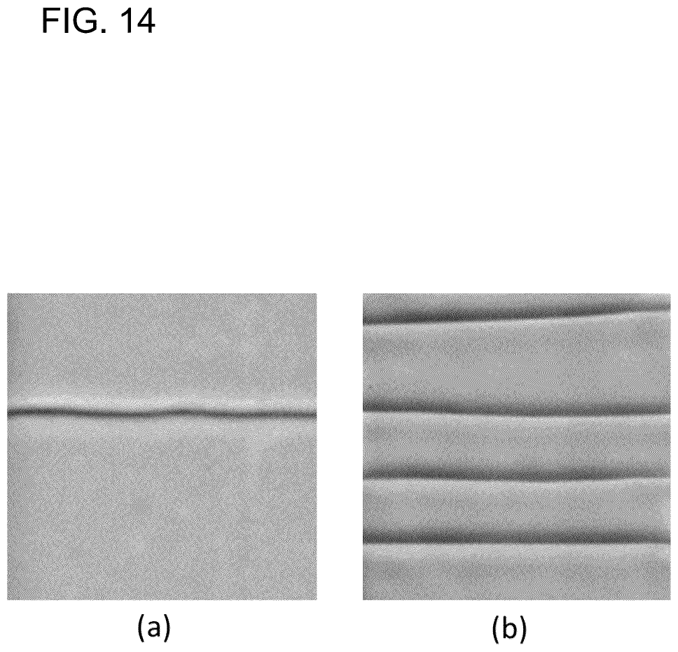

In the embodiment of the present disclosure, the conductive substrate according to the above-described embodiment of the present disclosure is used as the conductive substrate 107. In other words, a conductive substrate is used that contains copper and molybdenum and in which the first coefficient of linear expansion is smaller than the second coefficient of linear expansion. Further, the conductive substrate is layered on the semiconductor layer such that the third coefficient of linear expansion of the semiconductor layer is smaller than the fourth coefficient of linear expansion. By using the conductive substrate having such a preferred configuration, degradation of the semiconductor layer at high temperatures may be reduced, even if there is anisotropy in the coefficient of linear expansion of the semiconductor layer in the first direction and the second direction. To confirm the effect of the embodiment of the present disclosure, a structure corresponding to the semiconductor device illustrated in FIG. 4 was fabricated according to the processes described above, and a heating test was conducted. Here, in the example, a conductive substrate in which a substrate containing a first metal (Cu) and a second metal (Mo) was used, and a multilayer structure in which the semiconductor layer having an m-plane as a principle plane and the conductor substrate were layered such that the first coefficient of linear expansion was smaller than the second coefficient of linear expansion and the third coefficient of linear expansion was smaller than the fourth coefficient of linear expansion was used. Further, in the comparative example, a multilayer structure fabricated in the same manner as the example except that the conductive substrate was layered on the semiconductor layer such that the first coefficient of linear expansion was smaller than the second coefficient of linear expansion and the third coefficient of linear expansion was larger than the fourth coefficient of linear expansion was used. The thickness of the conductive substrate was 200 um in each case. Further, the semiconductor layer was an m-plane α-Ga₂O₃ layer in both the example and the comparative example. The number of cracks after heating at 450° C. for 60 minutes in the example and comparative example were inspected respectively, using a crack inspection system (manufactured by Softworks, Inc.). It was found that the number of cracks in the comparative example was 86 more than in the case of the example. Note that, the number of cracks was calculated by dividing the surface of the semiconductor layer into 289 sections and counting an instance of a crack in one section as 1. Images of the surface of the semiconductor layer taken by the crack inspection system (manufactured by Softworks, Inc.) after heating in the multilayer structure fabricated under the conditions of the example and the comparative example are shown in FIG. 14. FIG. 14(a) shows the results for the example and FIG. 14(b) shows the results for the comparison example. As evident from the number of crack results and FIG. 14, it may be seen that the embodiment of the present disclosure may reduce the degradation (crack occurrence) of the semiconductor layer at high temperature to a good degree.

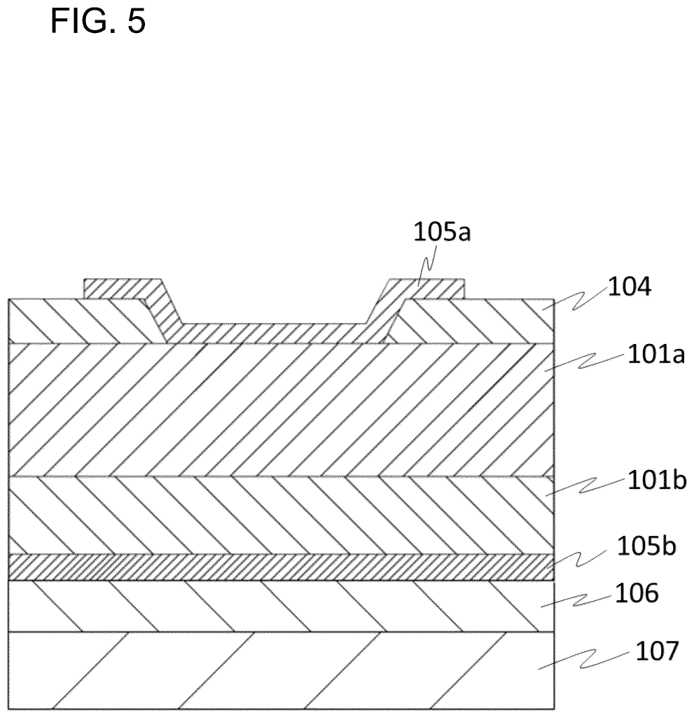

FIG. 5 illustrates an example of a Schottky barrier diode (SBD). In addition to the configuration of the SBD of FIG. 4, the SBD of FIG. 5 further includes an insulator layer 104. More specifically, the SBD includes the n− semiconductor layer 101a, the n+ semiconductor layer 101b, the conductive adhesive layer 106, the conductive substrate 107, the Schottky electrode 105a, the ohmic electrode 105b, and the insulator layer 104.

Examples of the material of the insulator layer 104 include GaO, AlGaO, InAlGaO, AlInZnGaO₄, AlN, Hf₂O₃, SiN, SiON, Al₂O₃, MgO, GdO, SiO₂ and Si₃N₄. In the embodiment of the present disclosure, the material of the insulator layer 104 preferably has a corundum structure. By using an insulator having a corundum structure in the insulator layer, the function of semiconductor properties at the interface may be well expressed. The insulator layer 104 is provided between the n− semiconductor layer 101a and the Schottky electrode 105a. The insulator layer may be formed by a known method, such as sputtering, vacuum deposition, or CVD.

The formation method and material of the Schottky electrode and the ohmic electrode are the same as in the case of the SBD in FIG. 4. For example, the electrode may be formed of a metal such as Al, Mo, Co, Zr, Sn, Nb, Fe, Cr, Ta, Ti, Au, Pt, V, Mn, Ni, Cu, Hf, W, Ir, Zn, In, Pd, Nd or Ag or their alloys, a metal oxide conductive film such as tin oxide, zinc oxide, indium oxide, indium tin oxide (ITO), and indium zinc oxide (IZO), organic conductive compounds such as polyaniline, polythiophene and polypyrrole, or mixtures thereof, by using a known method such as sputtering, vacuum deposition, crimping, and CVD.

The SBD in FIG. 5 has even better insulation characteristics and higher current controllability than the SBD in FIG. 4.

### (MOSFET)

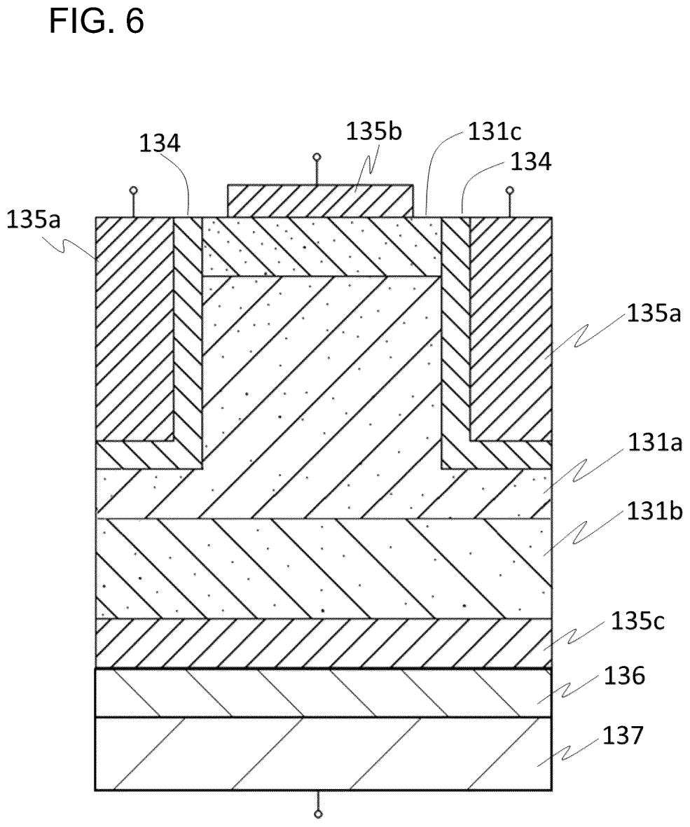

An example of a case where the semiconductor device of the present disclosure is a MOSFET is illustrated in FIG. 6. The MOSFET in FIG. 6 is a trench-type MOSFET and includes an n− semiconductor layer 131a, n+ semiconductor layers 131b and 131c, a conductive adhesive layer 136, a conductive substrate 137, a gate insulating film 134, a gate electrode 135a, a source electrode 135b and a drain electrode 135c.

The conductive adhesive layer 136 having a thickness of, for example, 50 nm to 50 μm is formed on the conductive substrate 137. The drain electrode 135c is formed on the conductive adhesive layer 136. The n+ semiconductor layer 131b having a thickness of, for example, 100 nm to 100 μm is formed on the drain electrode 135c, and the n− semiconductor layer 131a having a thickness of, for example, 100 nm to 100 μm is formed on the n+ semiconductor layer 131b. Further, the n+ semiconductor layer 131c is formed on the n− semiconductor layer 131a, and the source electrode 135b is formed on the n+ semiconductor layer 131c.

A plurality of trench grooves that each extend through the n+ semiconductor layer 131c and have a depth reaching a location partway along the n− semiconductor layer 131a are formed in the n− semiconductor layer 131a and the n+ semiconductor layer 131c. The gate electrode 135a is formed embedded in the trench grooves via the gate insulating film 134 having a thickness of, for example, 10 nm to 1 μm.

In the ON state of the MOSFET in FIG. 6, when a voltage is applied between the source electrode 135b and the drain electrode 135c and a positive voltage is applied to the gate electrode 135a with respect to the source electrode 135b, a channel layer is formed on a side surface of the n− semiconductor layer 131a, electrons are injected into the n− semiconductor layer 131a, and the MOSFET turns on. In the OFF state, when the voltage of the gate electrode 135a is set to 0 V, the channel layer is no longer formed, the n− semiconductor layer 131a is filled with a depletion layer, and the MOSFET turns off.

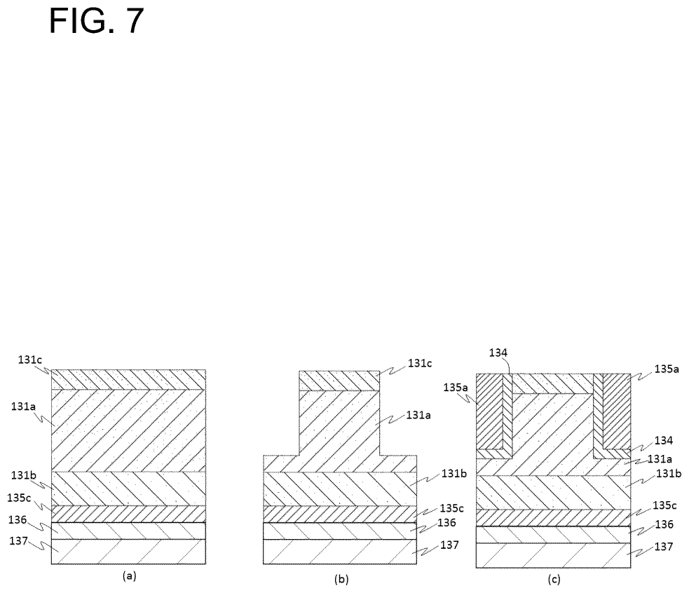

FIG. 7 illustrates a part of the manufacturing process of the MOSFET illustrated in FIG. 6. Using the multilayer body illustrated in FIG. 7(a), for example, an etching mask is provided in a predetermined region of the n− semiconductor layer 131a and the n+ semiconductor layer 131c. Then, the etching mask is used as a mask to perform anisotropic etching using a reactive ion etching method, as illustrated in FIG. 7(b) such that trench grooves each having a depth spanning from the surface of the n+ semiconductor layer 131c to a location partway along the n− semiconductor layer 131a are formed. Next, as illustrated in FIG. 7(c), the gate insulating film 134 having a thickness of, for example, 50 nm to 1 μm is formed on the sides and bottom of each trench groove using a known method such as thermal oxidation, vacuum deposition, sputtering, or CVD. Then, using CVD, vacuum deposition, or sputtering, a gate electrode material such as polysilicon is formed in the trench grooves to a thickness less than or equal to the thickness of the n− semiconductor layer.

Further, a power MOSFET may be manufactured by forming the source electrode 135b on the n+ semiconductor layer 131c and the drain electrode 135c on the n+ semiconductor layer 131b using a known method such as vacuum evaporation, sputtering, or CVD. Note that the electrode material for each of the source electrode and the drain electrode may be a known electrode material. Examples of the electrode material include metals such as Al, Mo, Co, Zr, Sn, Nb, Fe, Cr, Ta, Ti, Au, Pt, V, Mn, Ni, Cu, Hf, W, Ir, Zn, In, Pd, Nd and Ag or their alloys, metal oxide conductive films such as tin oxide, zinc oxide, indium oxide, indium tin oxide (ITO), and indium zinc oxide (IZO), and organic conductive compounds such as polyaniline, polythiophene, and polypyrrole or their mixtures.

The MOSFET obtained as described above has even better breakdown voltage resistance than a conventional trench-type MOSFET. Note that, while FIG. 6 illustrates an example of a trench-type vertical MOSFET, the embodiment of the present disclosure is not limited to this and may be applied to various types of MOSFETs. For example, the trench groove in FIG. 6 may be dug down to a depth that reaches the bottom of the n− semiconductor layer 131a to reduce series resistance.

### (SIT)

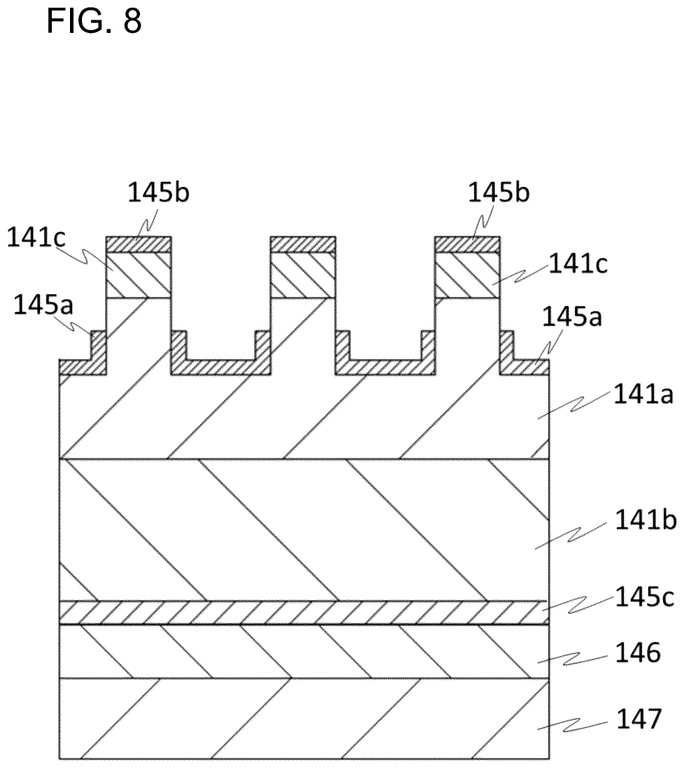

FIG. 8 illustrates an example of a case where the semiconductor device is an SIT. The SIT in FIG. 8 includes an n− semiconductor layer 141a, n+ semiconductor layers 141b and 141c, a conductive adhesive layer 146, a conductive substrate 147, a gate electrode 145a, a source electrode 145b, and a drain electrode 145c.

The conductive substrate 147 having a thickness of, for example, 100 nm to 100 μm is formed on the drain electrode 145c, and the conductive adhesive layer 146 having a thickness of, for example, 50 nm to 50 μm is formed on the conductive support layer 147. The n+ semiconductor layer 141b having a thickness of, for example, 100 nm to 100 μm is formed on the conductive adhesive layer 146, and the n− semiconductor layer 141a having a thickness of, for example, 100 nm to 100 μm is formed on the n+ semiconductor layer 141b. Further, the n+ semiconductor layer 141c is formed on the n− semiconductor layer 141a, and the source electrode 145b is formed on the n+ semiconductor layer 141c.

A plurality of trench grooves that each extend through the n+ semiconductor layer 141c and have a depth reaching a location partway along the n− semiconductor layer 141a are formed in the n− semiconductor layer 141a. The gate electrode 145a is formed on the n− semiconductor layer 141a in the trench grooves. In the ON state of the SIT in FIG. 8, when a voltage is applied between the source electrode 145b and the drain electrode 145c and a positive voltage is applied to the gate electrode 145a with respect to the source electrode 145b, a channel layer is formed in the n− semiconductor layer 141a, electrons are injected into the n− semiconductor layer 141a, and the SIT turns on. In the OFF state, when the voltage of the gate electrode 145a is set to 0 V, the channel layer is no longer formed, the n− semiconductor layer 141a is filled with a depletion layer, and the SIT turns off.

In the embodiment of the present disclosure, the SIT in FIG. 8 may be manufactured in the same way as the MOSFET in FIG. 7. More specifically, for example, an etching mask is provided in a predetermined region of the n− semiconductor layer 141a and the n+ semiconductor layer 141c, and the etching mask is used as a mask to perform anisotropic etching using a reactive ion etching method such that trench grooves each having a depth spanning from the surface of the n+ semiconductor layer 141c to a location partway along the n− semiconductor layer 141a are formed. Next, a gate electrode material such as polysilicon is formed in the trench grooves by a method such as CVD, vacuum evaporation, or sputtering to a thickness less than or equal to the thickness of the n− semiconductor layer. Further, the SIT may be manufactured by forming the source electrode 145b on the n+ semiconductor layer 141c and the drain electrode 145c on the n+ semiconductor layer 141b by using a known method such as vacuum evaporation, sputtering, or CVD. The electrode material of each of the source electrode and the drain electrode may be a known electrode material. Examples of the electrode material include Al, Mo, Co, Zr, Sn, Nb, Fe, Cr, Ta, Ti, Au, Pt, V, Mn, Ni, Cu, Hf, W, Ir, Zn, In, Pd, Nd and Ag or their alloys, metal oxide conductive films such as tin oxide, zinc oxide, indium oxide, indium tin oxide (ITO), indium zinc oxide (IZO), and organic conductive compounds such as polyaniline, polythiophene, or polypyrrole or their mixtures.

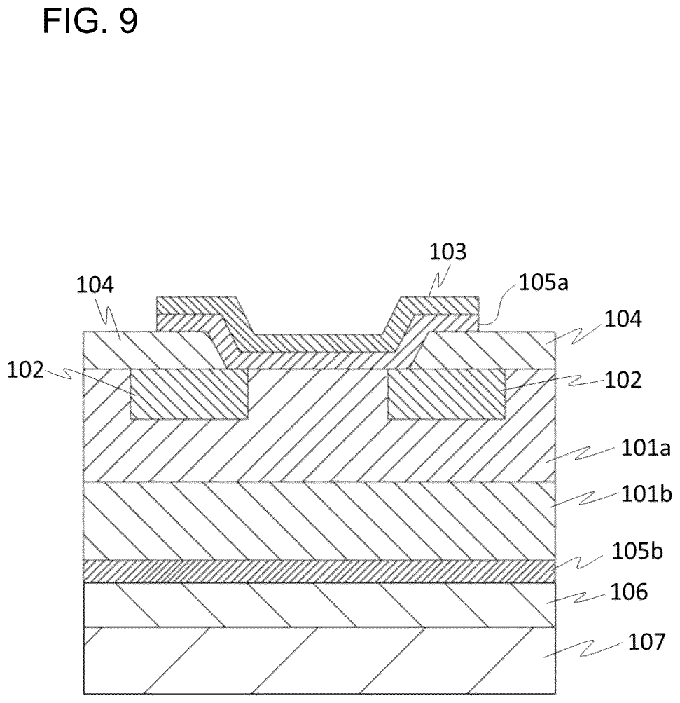

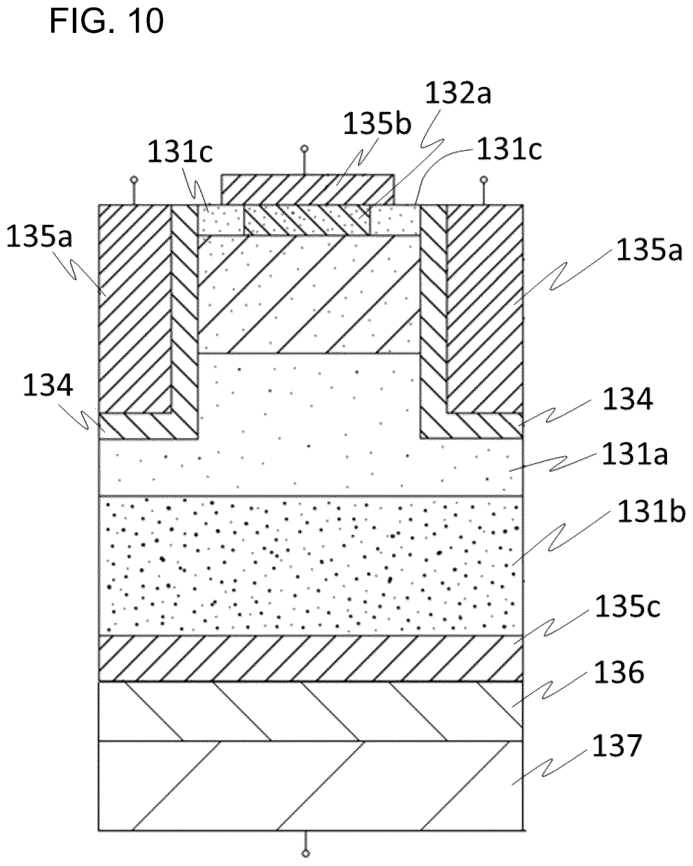

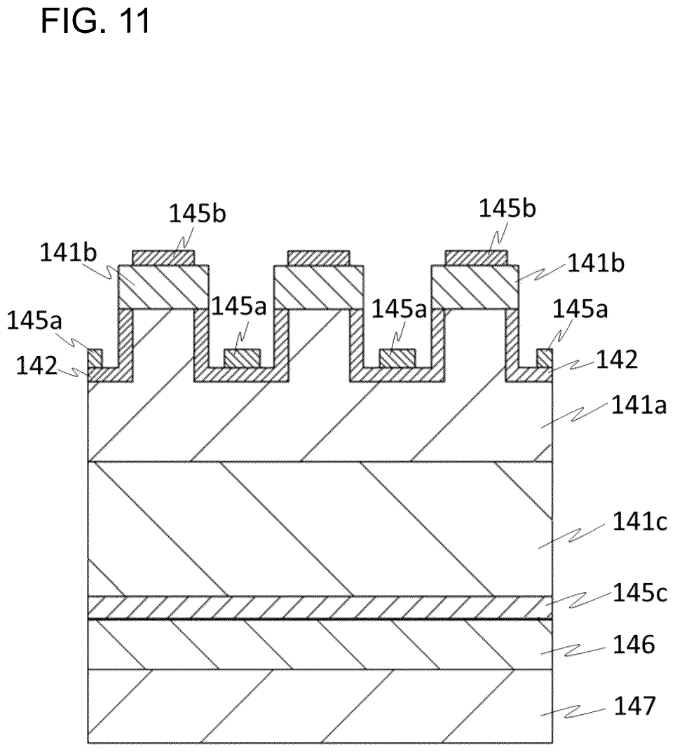

The above examples are examples in which a p semiconductor is not used. However, the embodiment of the present disclosure is not limited to these examples and a p semiconductor may be used. Examples using a p semiconductor are illustrated in FIGS. 9 to 11. These semiconductor devices may be manufactured in the same manner as the above examples. Note that the p semiconductor may be the same material as the n semiconductor and may contain a p-type dopant, or may be a different p semiconductor. Note that multiple embodiments of the present disclosure described above may be combined or some components may be applied to other embodiments, and any and all such modifications belong to the embodiments of the present disclosure.

The above-described semiconductor devices are particularly useful for power devices. Examples of the semiconductor device include diodes (e.g., PN diodes, Schottky barrier diodes, and junction barrier Schottky diodes) and transistors (e.g., MESFETs), among which diodes are preferred, and Schottky barrier diodes (SBDs) are more preferred.

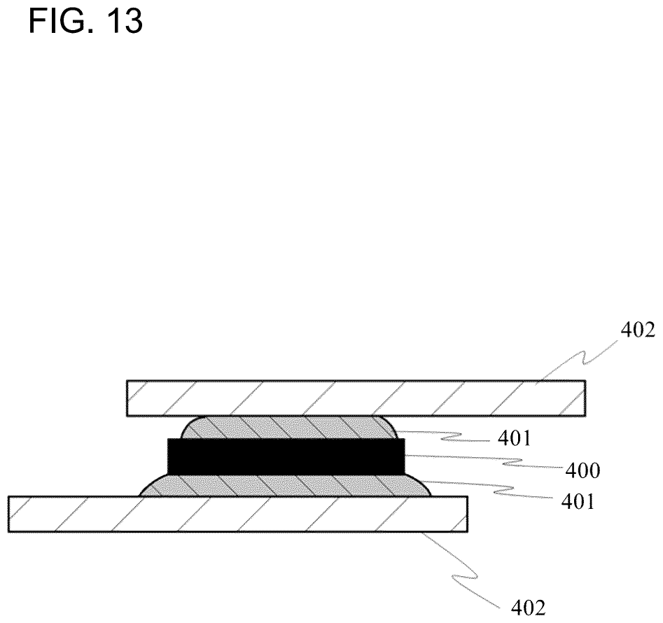

In addition to the above, the semiconductor device according to the embodiment of the present disclosure is also suitable for use as a semiconductor apparatus by bonding the semiconductor device to a lead frame, a circuit board, or a heat sink via a bonding member by a conventional method, particularly suitable for use as a power module, an inverter, or a converter, and further suitable for use in a semiconductor system employing a power supply, for example. A suitable example of the semiconductor device is illustrated in FIG. 13. In the semiconductor device in FIG. 13, both sides of a semiconductor device 400 are bonded to a lead frame, a circuit board or a heat dissipation substrate 402 by a solder 401, respectively. With this configuration, the semiconductor device may be made to have excellent heat dissipation. Note that, in the embodiment of the present disclosure, it is preferable that the area around the bonding member such as a solder is sealed with resin.

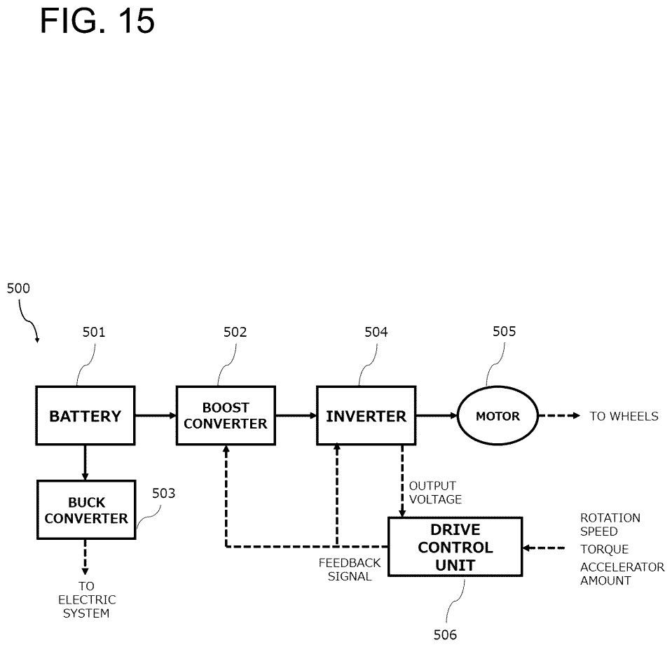

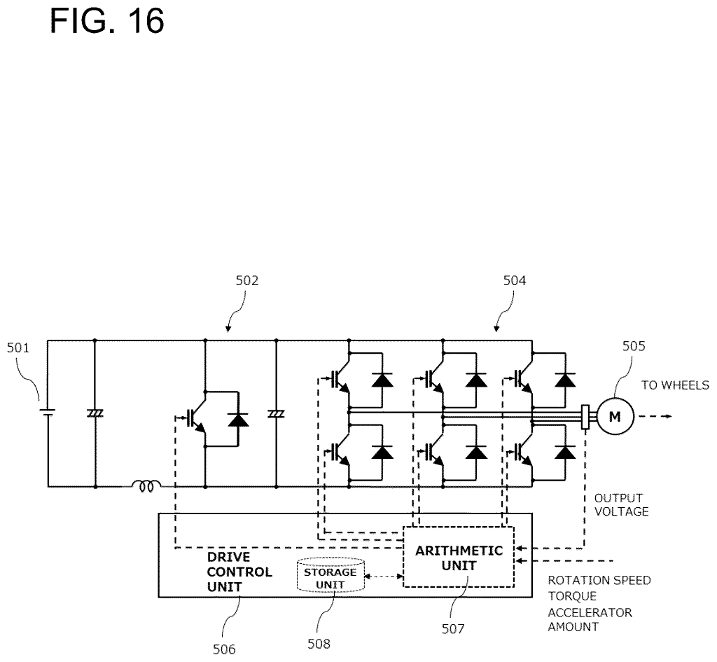

In order to exhibit the functions described above, the multilayer, the semiconductor element and/or the semiconductor device of the disclosure described above can be applied to a power converter such as an inverter or a converter. More specifically, it can be applied as a diode incorporated in the inverter or converter, a thyristor, a power transistor, an IGBT (Insulated Gate Bipolar Transistor), a MOSFET (Metal-Oxide-Semiconductor Field Effect Transistor or the like as a switching element. FIG. 15 is a block diagram illustrating an exemplary control system applying a multilayer, a semiconductor clement and/or a semiconductor device according to an embodiment of the disclosure, and FIG. 16 is a circuit diagram of the control system particularly suitable for applying to a control system of an electric vehicle.

As shown in FIG. 15, the control system 500 includes a battery (power supply) 501, a boost converter 502, a buck converter 503, an inverter 504, a motor (driving object) 505, a drive control unit 506, which are mounted on an electric vehicle. The battery 501 consists of, for example, a storage battery such as a nickel hydrogen battery or a lithium-ion battery. The battery 501 can store electric power by charging at the power supply station or regenerating at the time of deceleration, and to output a direct current (DC) voltage required for the operation of the driving system and the electrical system of the electric vehicle. The boost converter 502 is, for example, a voltage converter in which a chopper circuit is mounted, and can step-up DC voltage of, for example, 200V supplied from the battery 501 to, for example, 650V by switching operations of the chopper circuit. The step-up voltage can be supplied to a traveling system such as a motor. The buck converter 503 is also a voltage converter in which a chopper circuit is mounted, and can step-down DC voltage of, for example, 200V supplied from the battery 501 to, for example, about 12V. The step-down voltage can be supplied to an electric system including a power window, a power steering, or an electric device mounted on a vehicle.

The inverter 504 converts the DC voltage supplied from the boost converter 502 into three-phase alternating current (AC) voltage by switching operations, and outputs to the motor 505. The motor 505 is a three-phase AC motor constituting the traveling system of an electric vehicle, and is driven by an AC voltage of the three-phase output from the inverter 504. The rotational driving force is transmitted to the wheels of the electric vehicle via a transmission mechanism (not shown).

On the other hand, actual values such as rotation speed and torque of the wheels, the amount of depression of the accelerator pedal (accelerator amount) are measured from an electric vehicle in cruising by using various sensors (not shown), The signals thus measured are input to the drive control unit 506. The output voltage value of the inverter 504 is also input to the drive control unit 506 at the same time. The drive control unit 506 has a function of a controller including an arithmetic unit such as a CPU (Central Processing Unit) and a data storage unit such as a memory, and generates a control signal using the inputted measurement signal and outputs the control signal as a feedback signal to the inverters 504, thereby controlling the switching operation by the switching elements. The AC voltage supplied to the motor 505 from the inverter 504 is thus corrected instantaneously, and the driving control of the electric vehicle can be executed accurately. Safety and comfortable operation of the electric vehicle is thereby realized. In addition, it is also possible to control the output voltage to the inverter 504 by providing a feedback signal from the drive control unit 506 to the boost converter 502.

FIG. 16 is a circuit configuration excluding the buck converter 503 in FIG. 15, in other words, a circuit configuration showing a configuration only for driving the motor 505. As shown in the FIG. 16, the semiconductor device of the disclosure is provided for switching control by, for example, being applied to the boost controller 502 and the inverter 504 as a Schottky barrier diode. The boost converter 502 performs chopper control by incorporating the semiconductor device into the chopper circuit of the boost converter 502. Similarly, the inverter 504 performs switching control by incorporating the semiconductor device into the switching circuit including an IGBT of the inverter 504. The current can be stabilized by interposing an inductor (such as a coil) at the output of the battery 501. Also, the voltage can be stabilized by interposing a capacitor (such as an electrolytic capacitor) between each of the battery 501, the boost converter 502, and the inverter 504.

As indicated by a dotted line in FIG. 16, an arithmetic unit 507 including a CPU (Central Processing Unit) and a storage unit 508 including a nonvolatile memory are provided in the drive control unit 506. Signal input to the drive control unit 506 is given to the arithmetic unit 507, and a feedback signal for each semiconductor element is generated by performing the necessary operation. The storage unit 508 temporarily holds the calculation result by the calculation unit 507, stores physical constants and functions necessary for driving control in the form of a table, and outputs the physical constants, functions, and the like to the arithmetic unit 507 as appropriate. The arithmetic unit 507 and the storage unit 508 can be provided by a known configuration, and the processing capability and the like thereof can be arbitrarily selected.

As shown in FIGS. 15 and 16, a diode and a switching element such as a thyristor, a power transistor, an IGBT, a MOSFET and the like is employed for the switching operation of the boost converter 502, the buck converter 503 and the inverter 504 in the control system 500. The use of gallium oxide (Ga₂O₃) specifically corundum-type gallium oxide (α-Ga₂O₃) as its materials for these semiconductor devices greatly improves switching properties. Further, extremely outstanding switching performance can be expected and miniaturization and cost reduction of the control system 500 can be realized by applying a multilayer, a semiconductor element and/or a semiconductor device of the disclosure. That is, each of the boost converter 502, the buck converter 503 and the inverter 504 can be expected to have the benefit of the disclosure, and the effect and the advantages can be expected in any one or combination of the boost converter 502, the buck converter 503 and the inverter 504, or in any one of the boost converter 502, the buck converter 503 and the inverter 504 together with the drive control unit 506. The control system 500 described above is not only applicable to the control system of an electric vehicle of the semiconductor device of the disclosure, but can be applied to a control system for any applications such as to step-up and step-down the power from a DC power source, or convert the power from a DC to an AC. It is also possible to use a power source such as a solar cell as a battery.

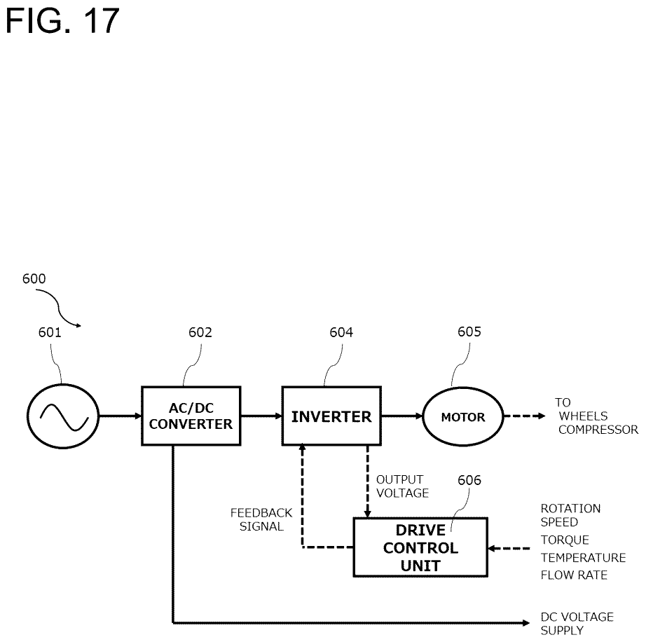

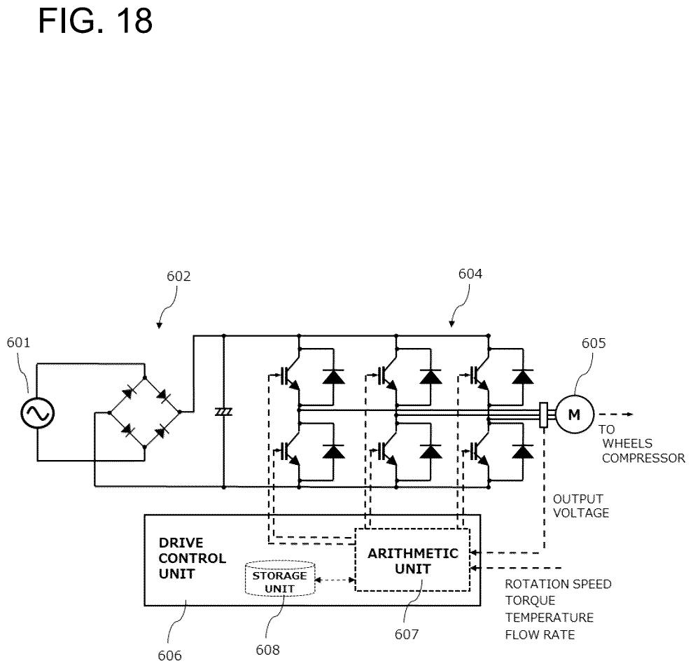

FIG. 17 is a block diagram illustrating another exemplary control system applying a semiconductor element or a semiconductor device according to an embodiment of the disclosure, and FIG. 18 is a circuit diagram of the control system suitable for applying to infrastructure equipment and home appliances or the like operable by the power from the AC power source.

As shown in FIG. 17, the control system 600 is provided for inputting power supplied from an external, such as a three-phase AC power source (power supply) 601, and includes an AC/DC converter 602, an inverter 60, a motor (driving object) 605 and a drive control unit 606 that can be applied to various devices described later. The three-phase AC power supply 601 is, for example, a power plant (such as a thermal, hydraulic, geothermal, or nuclear plant) of an electric power company, whose output is supplied as an AC voltage while being downgraded through substations. Further, the three-phase AC power supply 601 is installed in a building or a neighboring facility in the form of a private power generator or the like for supplying the generated power via a power cable. The AC/DC converter 602 is a voltage converter for converting AC voltage to DC voltage. The AC/DC converter 602 converts AC voltage of 100V or 200V supplied from the three-phase AC power supply 601 to a predetermined DC voltage. Specifically, AC voltage is converted by a transformer to a desired, commonly used voltage such as 3. 3V, 5V, or 12V. When the driving object is a motor, conversion to 12V is performed. It is possible to adopt a single-phase AC power supply in place of the three-phase AC power supply. In this case, same system configuration can be realized if an AC/DC converter of the single-phase input is employed.

The inverter 604 converts the DC voltage supplied from the AC/DC converter 602 into three-phase AC voltage by switching operations and outputs to the motor 605. Configuration of the motor 605 is variable depending on the control object. It can be a wheel if the control object is a train, can be a pump and various power source if the control objects a factory equipment, can be a three-phase AC motor for driving a compressor or the like if the control object is a home appliance. The motor 605 is driven to rotate by the three-phase AC voltage output from the inverter 604, and transmits the rotational driving force to the driving object (not shown).

There are many kinds of driving objects such as personal computer, LED lighting equipment, video equipment, audio equipment and the like capable of directly supplying a DC voltage output from the AC/DC converter 602. In that case the inverter 604 becomes unnecessary in the control system 600, and a DC voltage from the AC/DC converter 602 is supplied to the driving object directly as shown in FIG. 17. Here, DC voltage of 3.3V is supplied to personal computers and DC voltage of 5V is supplied to the LED lighting device for example.

On the other hand, rotation speed and torque of the driving object, measured values such as the temperature and flow rate of the peripheral environment of the driving object, for example, is measured using various sensors (not shown), these measured signals are input to the drive control unit 606. At the same time, the output voltage value of the inverter 604 is also input to the drive control unit 606. Based on these measured signals, the drive control unit 606 provides a feedback signal to the inverter 604 thereby controls switching operations by the switching element of the inverter 604. The AC voltage supplied to the motor 605 from the inverter 604 is thus corrected instantaneously, and the operation control of the driving object can be executed accurately. Stable operation of the driving object is thereby realized. In addition, when the driving object can be driven by a DC voltage, as described above, feedback control of the AC/DC converter 602 is possible in place of feedback control of the inverter 604.

FIG. 18 shows the circuit configuration of FIG. 17. As shown in FIG. 18, the semiconductor device of the disclosure is provided for switching control by, for example, being applied to the AC/DC converter 602 and the inverter 604 as a Schottky barrier diode. The AC/DC converter 602 has, for example, a circuit configuration in which Schottky barrier diodes are arranged in a bridge-shaped, to perform a direct-current conversion by converting and rectifying the negative component of the input voltage to a positive voltage. Schottky barrier diodes can also be applied to a switching circuit in IGBT of the inverter 604 to perform switching control. An inductor (e.g., coil) is interposed between the three-phase AC power supply 601 and the AC/DC converter 602 to stabilize the current, and a capacitor (e.g., electrolytic capacitor) is interposed between the AC/DC converter 602 and the inverter 604 to stabilize the voltage.

As indicated by a dotted line in FIG. 18, an arithmetic unit 607 including a CPU and a storage unit 608 including a nonvolatile memory are provided in the drive control unit 606. Signal input to the drive control unit 606 is given to the arithmetic unit 607, and a feedback signal for each semiconductor element is generated by performing the necessary operation. The storage unit 608 temporarily holds the calculation result by the arithmetic unit 607, stores physical constants and functions necessary for driving control in the form of a table, and outputs the physical constants, functions, and the like to the arithmetic unit 607 as appropriate. The arithmetic unit 607 and the storage unit 608 can be provided by a known configuration, and the processing capability and the like thereof can be arbitrarily selected.

In such a control system 600, similarly to the control system 500 shown in FIGS. 15 and 16, a diode or a switching element such as a thyristor, a power transistor, an IGBT, a MOSFET or the like is also applied for the purpose of the rectification operation and switching operation of the AC/DC converter 602 and the inverter 604. Switching performance can be improved by the use of gallium oxide (Ga₂O₃), particularly corundum-type gallium oxide (α-Ga₂O₃), as materials for these semiconductor elements. Further, extremely outstanding switching performance can be expected and miniaturization and cost reduction of the control system 600 can be realized by applying a semiconductor element or a semiconductor device of the disclosure. That is, each of the AC/DC converter 602 and the inverter 604 can be expected to have the benefit of the disclosure, and the effects and the advantages of the disclosure can be expected in any one or combination of the AC/DC converter 602 and the inverter 604, or in any of the AC/DC converter 602 and the inverter 604 together with the drive control unit 606.

Although the motor 605 has been exemplified in FIGS. 17 and 18, the driving object is not necessarily limited to those that operate mechanically. Many devices that require an AC voltage can be a driving object. It is possible to apply the control system 600 as long as electric power is obtained from AC power source to drive the driving object. The control system 600 can be applied to the driving control of any electric equipment such as infrastructure equipment (electric power facilities such as buildings and factories, telecommunication facilities, traffic control facilities, water and sewage treatment facilities, system equipment, labor-saving equipment, trains and the like) and home appliances (refrigerators, washing machines, personal computers, LED lighting equipment, video equipment, audio equipment and the like).

The semiconductor device of the present disclosure may be used in all fields, including semiconductors (e.g., compound semiconductor electronic devices), electronic and electric equipment components, optical and electrophotographic devices, and industrial components, but is particularly useful in power devices.

The embodiments of the present invention are exemplified in all respects, and the scope of the present invention includes all modifications within the meaning and scope equivalent to the scope of claims.

### REFERENCE SIGNS LIST

1 Deposition system (mist CVD system)
2a Carrier gas source
2b Carrier gas (dilution) source
3a Flow control valve
3b Flow control valve
4 Mist source
4a Raw material solution
4b Raw material particulates
5 Container
5a Water
6 Ultrasonic transducer
7 Deposition chamber
8 Hot plate
9 Supply tube
10 Substrate
101 Semiconductor layer
101a n− semiconductor layer
101b n+ semiconductor layer
102 p semiconductor layer
103 Metal layer
104 Insulator layer
105a Schottky electrode (other electrode layer)
105b Ohmic electrode (electrode layer)
106 Conductive adhesive layer
107 Conductive substrate
108 Underlying substrate
131a n− semiconductor layer
131b First n+ semiconductor layer
131c Second n+ semiconductor layer
132a p semiconductor layer
134 Gate insulating film
135a Gate electrode
135b Source electrode
135c Drain electrode
136 Conductive adhesive layer
137 Conductive substrate
141a n− semiconductor layer
141b First n+ semiconductor layer
141c Second n+ semiconductor layer
142 p semiconductor layer
145a Gate electrode
145b Source electrode
145c Drain electrode
146 Conductive adhesive layer
147 Conductive substrate
400 Semiconductor device
401 Solder
402 Circuit board (heat dissipation substrate)
500 Control system
501 Battery (power supply)
502 Boost converter
503 Buck converter
504 Inverter
505 Motor (drive target)
506 Drive control unit
507 Calculation unit
508 Memory unit
600 Control system
601 Three-phase AC power supply (power supply)
602 AC/DC converter
604 Inverter
605 Motor (drive target)
606 Drive control unit
607 Calculation unit
608 Memory unit

What is claimed is:

1. A multilayer structure comprising at least:
a semiconductor layer containing a crystalline oxide semiconductor as a major component; and
a conductive substrate layered on the semiconductor layer, wherein
the multilayer structure has a first direction in a plane perpendicular to a layering direction of the multilayer structure and a second direction perpendicular or substantially perpendicular to the first direction, and
a first coefficient of linear expansion being a coefficient of linear expansion in the first direction of the conductive substrate is smaller than a second coefficient of linear expansion being a coefficient of linear expansion in the second direction of the conductive substrate, and a third coefficient of linear expansion being a coefficient of linear expansion in the first direction of the semiconductor layer is smaller than a fourth coefficient of linear expansion being a coefficient of linear expansion in the second direction of the semiconductor layer.

2. The multilayer structure according to claim 1, wherein a difference between the first coefficient of linear expansion and the second coefficient of linear expansion is 2.0 ppm/K or less.

3. The multilayer structure according to claim 1, wherein the second coefficient of linear expansion is 10 ppm/K or less.

4. The multilayer structure according to claim 1, wherein
the crystalline oxide semiconductor has at least a first crystallographic axis and a second crystallographic axis,
a coefficient of linear expansion in a first crystallographic axis direction is smaller than a coefficient of linear expansion in a second crystallographic axis direction, and
the crystalline oxide semiconductor is parallel or substantially parallel to a layering direction of the multilayer structure and the first crystallographic axis.

5. The multilayer structure according to claim 4, wherein the crystalline oxide semiconductor has a corundum structure.

6. The multilayer structure according to claim 5, wherein the first crystallographic axis is an m-axis.

7. The multilayer structure according to claim 5, wherein the first direction of the semiconductor layer is an a-axis direction, and the second direction of the semiconductor layer is a c-axis direction.

8. The multilayer structure according to claim 1, wherein the crystalline oxide semiconductor contains at least one metal selected from aluminum, indium, and gallium.

9. The multilayer structure according to claim 1, wherein the crystalline oxide semiconductor contains at least gallium.

10. The multilayer structure according to claim 1, wherein a thickness of the conductive substrate is 200 μm or less.

11. A semiconductor device comprising at least the multilayer structure described in claim 1, and an electrode.

12. A semiconductor apparatus comprising at least a semiconductor device bonded to a lead frame, a circuit board or a heat dissipating substrate by a bonding member, wherein the semiconductor device is the semiconductor device described in claim 11.

13. A power conversion device using the semiconductor apparatus described in claim 12.

14. A control system using the semiconductor apparatus described in claim 12.
